(19) United States
(12) Patent Application Publication
(10) Pub. No.: US 2024/0282366 A1
(43) Pub. Date: Aug. 22, 2024

(54) AUGMENTED MEMORY COMPUTING: A NEW PATHWAY FOR EFFICIENT AI COMPUTATIONS

(71) Applicant: UNIVERSITY OF SOUTHERN CALIFORNIA, Los Angeles, CA (US)

(72) Inventors: Ajey Poovannummoottil JACOB, Los Angeles, CA (US); Akhilesh JAISWAL, Los Angeles, CA (US)

(73) Assignee: UNIVERSITY OF SOUTHERN CALIFORNIA, Los Angeles, CA (US)

(21) Appl. No.: 18/571,407

(22) PCT Filed: Jun. 20, 2022
(86) PCT No.: PCT/US2022/034194

§ 371 Date: Dec. 18, 2023

Related U.S. Application Data
(60) Provisional application No. 63/212,275, filed on Jun. 18, 2021.

(51) Int. Cl. G11C 11/419; G11C 11/418

(52) U.S. Cl. CPC G11C 11/419; G11C 11/418

(57) ABSTRACT

A novel approach for improving the power, performance, area metric for AI computations by dynamically augmenting (doubling) the memory storage capacity uses novel eight transistor SRAM bit-cells.

### CROSS-REFERENCE TO RELATED APPLICATIONS

This application claims the benefit of U.S. provisional application Ser. No. 63/212,275 filed Jun. 18, 2021, the disclosure of which is hereby incorporated in its entirety by reference herein.

### TECHNICAL FIELD

In at least one aspect, a novel approach for improving the power, performance, area metric for AI computations by dynamically augmenting (doubling) the memory storage capacity is provided.

### BACKGROUND

Memory-centric approaches, as in in-memory, near-memory computing have recently attracted considerable research interest for accelerating AI applications. AI and ML algorithms require huge memory and compute requirements. Advantageously, these algorithms are also error-resilient, which implies they can perform well even with few errors introduced in hardware computation.

Over decades the advances in hardware computing platforms have been driven by the remarkable scalability of the Metal-Oxide-Semiconductor Field Effect Transistors (MOSFETs) in accordance with Moore's Law [1]. Despite consistent improvement in power-performance-area (PPA) metrics, recent trends in data-intensive applications have pushed the state-of-the-art in hardware computing platforms to their limits [2]. Existing hardware solutions suffer from energy and throughput bottlenecks due to frequent data movement between multiple levels of the memory hierarchy and between memory-units and processing-cores [3]. To mitigate such bottlenecks various memory-centric approaches are being extensively explored by the research community. These include exploration of novel high-density emerging memory technologies [4], [5] and use of emerging computing approaches like in-memory and near-memory computing [6], [7].

It is well-known that the 6 transistor SRAM cell is the most widely used on-chip memory system due to its high robustness and fast read-write speed [8], [9]. However, a major drawback of SRAM is the associated high area overhead, limiting the amount of on-chip memory storage. Consequently, off-chip memory systems are used as high-density storage at the expense of speed and energy consumption. In fact, the data communication overhead associated with the movement of data from off-chip to on-chip memory forms a major source of energy consumption and compute latency [10]. Toward that end, Augmented Memory Computing (AMC) aims at increasing the on-chip storage on demand, thereby dynamically augmenting storage capacity for SRAM arrays that can cater to data intensive applications.

### SUMMARY

In at least one aspect, a novel approach for improving the power, performance, area metric for AI computations by dynamically augmenting (doubling) the memory storage capacity uses novel eight transistor SRAM bit-cells.

In another aspect, a novel memory-centric approach called “Augmented Memory Computing,” i.e., augmenting or increasing the memory storage capacity, is provided. In this approach, individual SRAM bit-cells can be dynamically reconfigured to store two bits of data instead of one.

In still another aspect, the novel SRAM bit-cells that can store more than one bit of data at the cost of slightly degraded bit-cell robustness. This slightly degraded bit-cell robustness is not of concern for AI applications due to their error resilience.

In still another aspect, an SRAM bit-cell that can dynamically augment its memory storage capacity is provided. This capability is not possible with today's state-of-the-art.

In still another aspect, the SRAM bit-cell can act in three different modes—6T SRAM like mode, two-port SRAM mode, and augmented memory compute mode SRAM+DRAM mode

In yet another aspect, an SRAM bit-cell that can store ternary data useful for ternary neural networks is provided. In this configuration, eight transistors per bit are required as opposed to 12 compared to state of the art.

In yet another aspect, a novel memory-centric paradigm—Augmented Memory Computing (AMC) for the acceleration of data-intensive applications like artificial intelligence and machine learning is provided.

In another aspect, a novel memory-centric compute paradigm called Augmented Memory Computing is provided. Advantageously, the storage capacity of on-chip SRAM-based memory can be increased dynamically for data-intensive computations.

In another aspect, an SRAM bit-cell that includes one or two additional transistors as compared to a conventional 6T SRAM bit-cell is provided.

In another aspect, a first 8T SRAM-bit cell includes a first transistor M1, a second transistor M2, a third transistor M3, a fourth transistor M4, a fifth transistor M5, a sixth transistor M6, a seventh transistor M7, and an eighth transistor M8. A four transistor SDRAM component includes a first transistor inverter and a second transistor inverter. The first transistor inverter includes the fifth transistor M5 and the sixth transistor M6 and the second transistor inverter includes the seventh transistor M7 and the eighth transistor M8. An output Q of the first transistor inverter is provided as input Vin2 to the second transistor inverter and an output QB of the second transistor inverter is provided as input Vin1 to the first transistor inverter. The first transistor M1 is a first access transistor in electrical communication with the output Q of first transistor inverter and first bit line BL. The third transistor M3 is a second access transistor in electrical communication with the output QB of second transistor inverter and a second bit line BLB. The second transistor M2 is a first additional transistor. The fourth transistor M4 is a second additional transistor. The second transistor M2 is interposed between the output QB of second transistor inverter and a terminal of the third transistor M3 with terminals of the second transistor M2 and the third transistor M3 connected in series. An output Vout3 of a combination of the second transistor M2 and the third transistor M3 is in electrical communication with a gate of the fourth transistor M4, the fourth transistor M4 having a first terminal connected to line BL-R and a second terminal connected to line SL. Finally, the first transistor M1 and the second transistor M2 are connected to a first wordline and the third transistor M3 is connected to a second wordline.

In another aspect, the first 8T SRAM-bit cell is configured such that when the first transistor M1, the second transistor M2, and the third transistor M3 are all ON, the SRAM-bit cell functioning as a 6T SRAM bit-cell 2.

In another aspect, the first 8T SRAM-bit cell is configured such that when the first transistor M1, the second transistor M2 is ON and the third transistor M3 is OFF with the SRAM-bit cell functioning similar to conventional two port 8T SRAM bit-cell with a de-coupled read port, data being read by pulling SL high and sensing a voltage change on BL-R.

In another aspect, the first 8T SRAM-bit cell is configured such that when the first transistor M1, the second transistor M2 is OFF and the third transistor M3 is ON.

In another aspect, a second 8T SRAM-bit cell includes a first transistor M1, a second transistor M2, a third transistor M3, a fourth transistor M4, a fifth transistor M5, a sixth transistor M6, a seventh transistor M7, and an eighth transistor M8. A four transistor SDRAM component includes a first transistor inverter and a second transistor inverter. The first transistor inverter includes the seventh transistor M7 and the fourth transistor M4 and the second transistor inverter includes the eighth transistor M8 and the third transistor M3. An output Q of first transistor inverter is provided as input Vin2 to the second transistor inverter and an output QB of second transistor inverter is provided as input Vin1 to the first transistor inverter. The fifth transistor M5 is a first additional transistor and the sixth transistor is a second additional transistor. The gates of the fifth transistor M5 and the sixth transistor M6 are connected to each other and to additional line EN. Terminals of the fifth transistor M5 are in series with terminals of the fourth transistor M4 while terminals of the sixth transistor M6 are in series with terminals of the third transistor M3. The first transistor M1 is a first access transistor having a terminal connected to output Q of the first transistor inverter and a terminal connected to line BL. The second transistor M2 is a second access transistor having a terminal connected to output QB of the first transistor inverter and to line BL1.

In another aspect, the second 8T SRAM-bit cell is configured such that when line EN is ON, the SRAM-bit cell functions like 6T SRAM bit-cell.

In another aspect, the second 8T SRAM-bit cell is configured such when line EN is OFF, the SRAM-bit cell stores data in a dynamic format wherein (Q, QB), are (1,0) or (0,1) or (1,1).

In another aspect, a third 8T SRAM-bit cell includes a first transistor M1, a second transistor M2, a third transistor M3, a fourth transistor M4, a fifth transistor M5, a sixth transistor M6, a seventh transistor M7, and an eighth transistor M8. A four transistor cross-coupled inverter component includes a first transistor inverter and a second transistor inverter. The first transistor inverter including the fifth transistor M5 and the sixth transistor M6 connected at a first node Vx and the second transistor inverter including the seventh transistor M7 and the eighth transistor M8 connected at a second node Vy. The first transistor M1 is a first access transistor in electrical communication with the gates of the seventh transistor M7 and the eighth transistor M8 which are connected together, the first transistor M1 also being in electrical communication with a first bit line BL. The second transistor M2 is a first additional transistor in electrical communication with the gates of transistor the fifth transistor M5 and the sixth transistor M6 which are connected together. The gates of both the first transistor M1 and the second transistor M2 are in electrical communication with a wordline WL1.

In another aspect, the 8T SRAM-bit cell includes a differential sense amplifier for SRAM in electrical communication with the first bit line BL and the second bit line BLB.

In another aspect, a 7T SRAM-bit cell includes a first transistor M1, a second transistor M2, a third transistor M3, a fourth transistor M4, a fifth transistor M5, a sixth transistor M6, and a seventh transistor M7. A cross-coupled inverters component includes a first transistor inverter and a second transistor inverter. The first transistor inverter includes the first transistor M1 and the third transistor M3 and the second transistor inverter includes the second transistor M2 and the fourth transistor M4. The fifth transistor M5 is a first access transistor in electrical communication with an output Q of the first transistor inverter and the gates of the second transistor M1 and the fourth transistor M3 which are connected together. The fifth transistor M5 is also in electrical communication with a first bit line BL. The sixth transistor M6 is a second access transistor in electrical communication with an output Qb of the second transistor inverter and the gates of the first transistor M1 and the third transistor M3 which are connected together. The sixth transistor M6 is also in electrical communication with a second bit line BLB. The seventh transistor M7 connects the cross-coupled inverter component to supply voltage VDD.

In another aspect, the 7T SRAM-bit cell is configured such that during Normal mode of operation, the seventh transistor M7 is kept ON.

In another aspect, the 7T SRAM-bit cell is configured such that during the Augmented mode, the seventh transistor M7 is switched OFF such that three different data patterns are stored on nodes (Q,QB) in a dynamic fashion.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

For a further understanding of the nature, objects, and advantages of the present disclosure, reference should be had to the following detailed description, read in conjunction with the following drawings, wherein like reference numerals denote like elements and wherein:

FIG. 1. 8T dual bit storage augmented bit-cell. The cell can store an SRAM-like and a DRAM-like date, simultaneously, in the augmented mode.

FIGS. 2A and 2B. (A) 6 transistor SRAM cell read SNM using SRAM bit-cell from a typical 22 nm library. (B) The read SNM for the 8 transistor augmented bit-cell. As seen the read SNM for the proposed bit-cells is similar to the library SRAM bit-cell, thereby demonstrating the asymmetry in the SRAM circuit does not drastically alter the cell stability.

FIG. 3. sensing scheme for the SRAM and DRAM data in the augmented 8T bit-cell. The SRAM data can be sensed through the differential bit-lines BL and BLB, while the DRAM data can be sensed using single-ended large-signal inverter-based sensing. Note, a FILO scheme ensures the DRAM data is not disturbed inadvertently.

FIG. 4. Plots depicting leakage of data stored on the dynamic node as a function of time for the DRAM-like bit storage in the 8T augmented cell at 85 C.

FIG. 5. 8T SRAM cell featuring almost all benefits of conventional 8T SRAM cell with an added feature of dynamically augmenting memory storage capacity to store two bits.

FIG. 6. An 8T SRAM cell that can be used for a single bit (like 6T SRAM cell) or ternary storage per bit-cell.

FIGS. 7A and 7B. 7T augmented ternary bit-cell in Normal mode. During the normal mode of operation, M6 is ON, thereby the 7T cell acts like a conventional 6T SRAM cell.

FIG. 8. 7T augmented cell showing parasitic capacitances at nodes Q and QB that act like dynamic nodes to store the ternary data (0,1), (1,0) or (0,0) in a DRAM-like fashion during the augmented mode of operation.

FIG. 9. Waveforms showing the writing of data (0,1)/data (1,0) into the augmented 7T SRAM cell when PMOS M6 is OFF.

FIG. 10. Data retention time for data (0,1)/data (1,0) at 85 C. The retention time improves with decreasing temperature.

FIG. 11. The writing of data (0,0) in the 7T augmented cell. In absence of positive feedback, WL can be activated and BL and BLB can be pulled low to write data (0,0).

FIGS. 12A and 12B. (A) For the Normal mode of operation, a differential sense amplifier can be used for sensing (B) For the case of Augmented mode two inverters along with a digital logic circuit are employed to sense ternary data (0,1), (1,0) and (0,0).

FIG. 13. Read waveform for data (0,1) at the end of retention time at 85 C.

### DETAILED DESCRIPTION

Reference will now be made in detail to presently preferred embodiments and methods of the present invention, which constitute the best modes of practicing the invention presently known to the inventors. The Figures are not necessarily to scale. However, it is to be understood that the disclosed embodiments are merely exemplary of the invention that may be embodied in various and alternative forms. Therefore, specific details disclosed herein are not to be interpreted as limiting, but merely as a representative basis for any aspect of the invention and/or as a representative basis for teaching one skilled in the art to variously employ the present invention.

It is also to be understood that this invention is not limited to the specific embodiments and methods described below, as specific components and/or conditions may, of course, vary. Furthermore, the terminology used herein is used only for the purpose of describing particular embodiments of the present invention and is not intended to be limiting in any way.

It must also be noted that, as used in the specification and the appended claims, the singular form “a,” “an,” and “the” comprise plural referents unless the context clearly indicates otherwise. For example, reference to a component in the singular is intended to comprise a plurality of components.

The term “comprising” is synonymous with “including,” “having,” “containing,” or “characterized by.” These terms are inclusive and open-ended and do not exclude additional, unrecited elements or method steps.

The phrase “consisting of” excludes any element, step, or ingredient not specified in the claim. When this phrase appears in a clause of the body of a claim, rather than immediately following the preamble, it limits only the element set forth in that clause; other elements are not excluded from the claim as a whole.

The phrase “consisting essentially of” limits the scope of a claim to the specified materials or steps, plus those that do not materially affect the basic and novel characteristic(s) of the claimed subject matter.

With respect to the terms “comprising,” “consisting of,” and “consisting essentially of,” where one of these three terms is used herein, the presently disclosed and claimed subject matter can include the use of either of the other two terms.

It should also be appreciated that integer ranges explicitly include all intervening integers. For example, the integer range 1-10 explicitly includes 1, 2, 3, 4, 5, 6, 7, 8, 9, and 10. Similarly, the range 1 to 100 includes 1, 2, 3, 4 . . . 97, 98, 99, 100. Similarly, when any range is called for, intervening numbers that are increments of the difference between the upper limit and the lower limit divided by 10 can be taken as alternative upper or lower limits. For example, if the range is 1.1. to 2.1 the following numbers 1.2, 1.3, 1.4, 1.5, 1.6, 1.7, 1.8, 1.9, and 2.0 can be selected as lower or upper limits.

The term “connected to” means that the electrical components referred to as connected to are in electrical communication. In a refinement, “connected to” means that the electrical components referred to as connected to are directly wired to each other. In another refinement, “connected to” means that the electrical components communicate wirelessly or by a combination of wired and wirelessly connected components. In another refinement, “connected to” means that one or more additional electrical components are interposed between the electrical components referred to as connected to with an electrical signal from an originating component being processed (e.g., filtered, amplified, modulated, rectified, attenuated, summed, subtracted, etc.) before being received to the component connected thereto.

The term “electrical communication” means that an electrical signal is either directly or indirectly sent from an originating electronic device to an electronic receiving device. Indirect electrical communication can involve the processing of the electrical signal, including but not limited to, filtering of the signal, amplification of the signal, the rectification of the signal, modulation of the signal, attenuation of the signal, adding of the signal with another signal, subtracting the signal from another signal, subtracting another signal from the signal, and the like. Electrical communication can be accomplished with wired components, wirelessly connected components, or a combination thereof.

The term “one or more” means “at least one,” and the term “at least one” means “one or more.” The terms “one or more” and “at least one” include “plurality” as a subset.

The term “substantially,” “generally,” or “about” may be used herein to describe disclosed or claimed embodiments. The term “substantially” may modify a value or relative characteristic disclosed or claimed in the present disclosure. In such instances, “substantially” may signify that the value or relative characteristic it modifies is within ±0%, 0.1%, 0.5%, 1%, 2%, 3%, 4%, 5% or 10% of the value or relative characteristic.

The term “electrical signal” refers to the electrical output from an electronic device or the electrical input to an electronic device. The electrical signal is characterized by voltage and/or current. The electrical signal can be stationary with respect to time (e.g., a DC signal) or it can vary with respect to time.

The term “electronic component” refers is any physical entity in an electronic device or system used to affect electron states, electron flow, or the electric fields associated with the electrons. Examples of electronic components include, but are not limited to, capacitors, inductors, resistors, thyristors, diodes, transistors, etc. Electronic components can be passive or active.

The term “electronic device” or “system” refers to a physical entity formed from one or more electronic components to perform a predetermined function on an electrical signal.

It should be appreciated that in any figure for electronic devices, a series of electronic components connected by lines (e.g., wires) indicates that such electronic components are in electrical communication with each other. Moreover, when lines directed connect one electronic component to another, these electronic components can be connected to each other as defined above.

Transistors in electrical communication or connected together can have a source connected to drain or a drain connect to a drain or a source connected to a source unless it is specified that connection is to the gate.

Throughout this application, where publications are referenced, the disclosures of these publications in their entireties are hereby incorporated by reference into this application to more fully describe the state of the art to which this invention pertains.

### Abbreviations

8T means eight transistor.
“AI” means artificial intelligence.
“AMC” means Augmented Memory Computing.
“BL” means bit lines.
“ML” means machine learning.
“T” means transistor.
“WL” means word line.
“Vdd” is the system voltage (e.g., 1 to 5 volts).

In general, a family of novel SRAM bit-cells using two different bit-cell topology is provided. In the first topology, an 8 transistor (8T) augmented SRAM cell includes two additional transistors as compared to a 6T cell, wherein the 8T augmented bit-cell can simultaneously store an SRAM-like and a DRAM-like data based on the applied voltages. In a second topology, a 7T augmented bit-cell can store ternary data (−1, 0, +1) per bit-cell in a dynamic format as opposed to storing a binary data (0,1) as in a conventional 6T SRAM cell. It should be appreciated that both the augmented bit-cells can function like normal SRAM cells with comparative read-write margins and speed. As such, the bit-cells can be operated in two distinct modes. In the Normal mode these bit-cells function like conventional 6T bit-cell storing a binary data, while in Augmented mode, the bit-cells can store more data (either two bits for the 8T augmented cell, and ternary bits for the 7T augmented cell), thereby dynamically increasing the memory storage capacity.

Moreover, in comparison to in-memory computing, AMC does not rely on complicated approximate analog computing and hence is more robust. This does not imply that AMC cannot be used in conjunction with in-memory computing. As discussed below, AMC can be combined with existing in-memory computing approaches for improved energy efficiency and throughput [6], [11], [12]. Finally, although AMC is conceptually independent of in-memory computing paradigms, it can be easily combined with existing in-memory processing schemes. Thus, AMC presents a novel approach for memory-centric computing, along with other existing memory-centric approaches (like in-memory/near-memory computing).

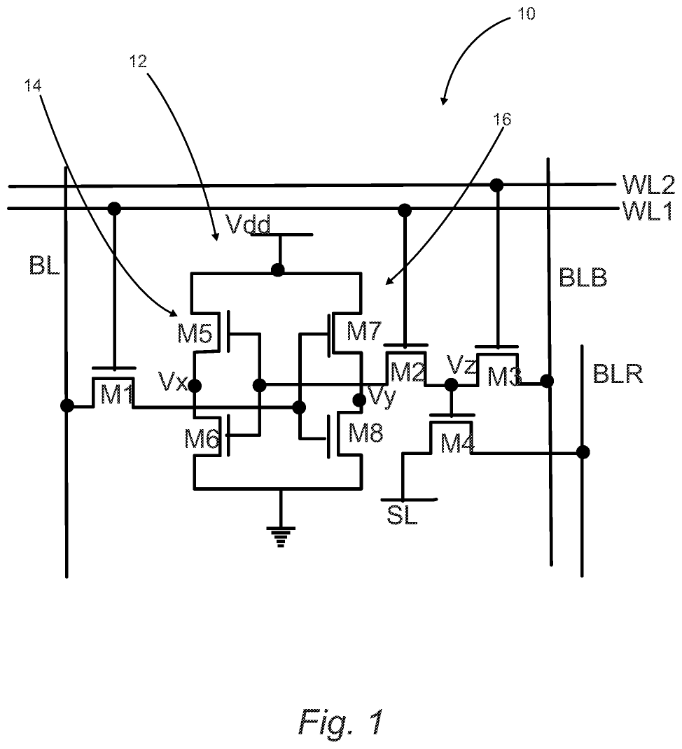

In an embodiment, an 8T dual storage augmented bit-cell is provided. As set forth above, augmented bit-cells can increase their storage capacity dynamically while also functioning like conventional SRAM bit-cells in the Normal mode. For a dual bit augmented storage, two additional transistors are added to the 6T SRAM cell, as shown in FIG. 1. This bit-cell can operate in two distinct modes—the Normal mode and the Augmented mode. The SRAM cell can be configured in the Normal or Augmented mode at a sub-array level granularity.

Referring to FIG. 1, an 8T SRAM-bit cell 10 includes a first transistor M1, a second transistor M2, a third transistor M3, a fourth transistor M4, a fifth transistor M5, a sixth transistor M6, a seventh transistor M7, and an eighth transistor M8. The 8T SRAM-bit cell 10 includes a four transistor SDRAM component 12 (e.g., a cross-coupled inverter) having a first transistor inverter 14 and a second transistor inverter 16. First transistor inverter 14 includes transistors M5 and M6 while the second transistor inverter 16 includes transistors M7 and M8. In a refinement, the first transistor inverter 14 and the second transistor inverter 16 are CMOS inverters. Characteristically, SRAM-bit cell 10 also includes access transistors M1 in electrical communication with the gates of transistors M7 and M8 which are connected together. Access transistors M1 is also in electrical communication with first bit line BL. Similarly, SRAM-bit cell 10 also includes additional transistor M2 in electrical communication with the gates of transistors M5 and M6 which are connected together. The gates of both transistors M1 and M2 are in electrical communication with wordline WL1. SRAM-bit cell 10 also includes access transistor M3 in electrical communication with additional transistor M2 both of which are in electrical communication with the gate of additional transistor M4. Additional transistor M4 is in electrical communication with line SL (e.g., an electrical line such as a source line) and line BLR (e.g., read bit line). The gate of access transistor M3 is in electrical communication with wordline WL2. Access transistor is also in electrical communication with second bit line BLB.

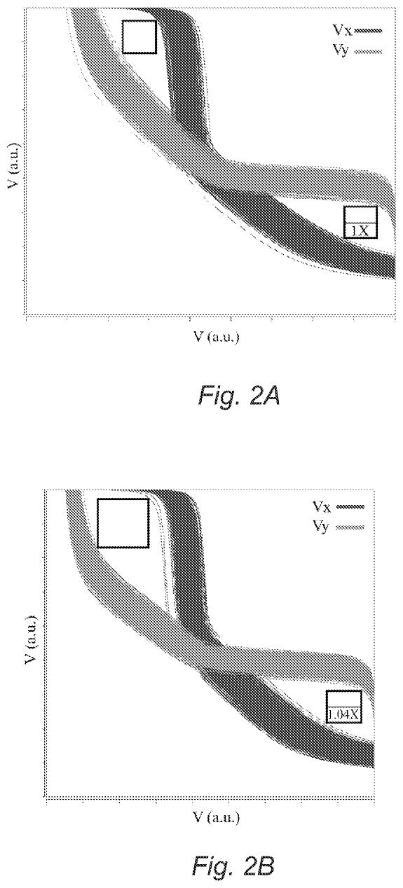

For the Normal mode of operation, both the wordlines WL1 and WL2 are activated, simultaneously, during the read and write operations. The resulting SRAM read and write operations are similar to the 6T cell, except that the SRAM is asymmetric due to the presence of an additional access transistor (M3) on the BLB side of the 8T SRAM cell. As shown in FIG. 2, using 1000 Monte-Carlo simulations for a typical 22 nm device, almost no change is observed in static noise margins, compared to the 6T bit-cell. Thus, the asymmetric nature of the 8T bit-cell leads to minimal alteration of static noise margins and hence the cell stability. Additionally, the SL line and the BLR line are kept at 0V during the Normal mode of operation. This ensures no current flows through transistor M4, irrespective of the voltage at its gate at the node Vz. In summary, the 8T bit-cell shown in FIG. 1 can be operated similar in functionality to the conventional 6T SRAM cell when both WL1 and WL2 are simultaneously activated. This also implies that a conventional differential sense-amplifier can be used to sense the data stored in the SRAM cell.

Advantageously, the presented 8T bit-cell can be used to improve cell-stability and achieve lower operating voltages compared to the 6T bit-cell using the well-known pulsed wordline activation scheme [14]. This can be achieved by using transistor M4 as a de-coupled read port. For improved stability, WL1 is activated first using a short duration pulse, keeping WL2 OFF. This would ensure node Vz is charged or discharged based on the data stored at node Vy. Essentially, by pulsed activation of the wordline WL1, we are copying the SRAM data into the node Vz. Since the pulse duration of the signal on WL1 would be much smaller than conventional 6T SRAM the possibility of read disturb is minimal [14]. After the pulsed activation of WL1, the SL is pulled to VDD. Subsequently, a large signal inverter-based sensing can detect the voltage change on BLB. Thus, the proposed 8T bit-cell can be used in conjunction with a pulsed WL scheme to improve cell-stability.

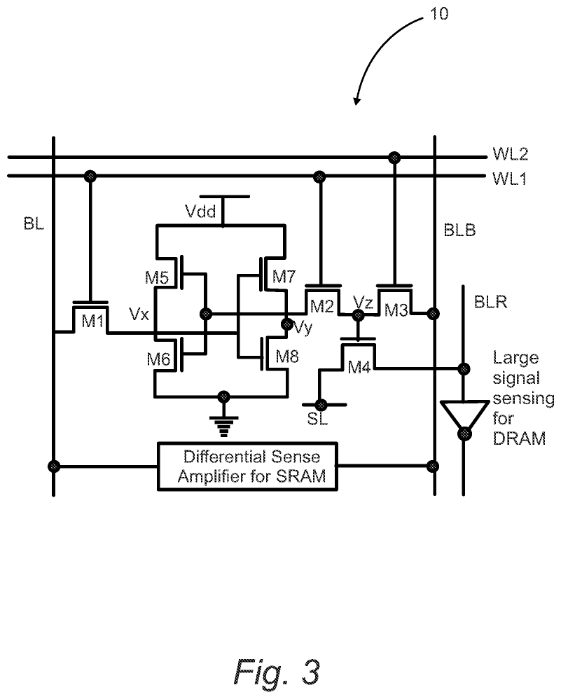

Still referring to FIG. 1, in the augmented mode, the 8T bit-cell stores two bits of data, simultaneously. The SRAM-like static data is stored in the cross-coupled inverter pair as complementary voltages on nodes Vx and Vy, similar to the conventional 6T SRAM storage; while the two transistors M3 and M4 store a DRAM-like data on the dynamic node Vz. In fact, transistors M3 and M4 form a 2 transistor embedded DRAM cell, which can be written by activating WL2, and can be read through transistor M4 using lines SL and BLR. For the DRAM write operation, line WL2 is pulled high and data is written into the DRAM node Vz through the line BLB. Note, due to the presence of an NMOS only access transistor M3, we use voltage boosting on WL2 for writing a high value at the dynamic node Vz. During the write operation, the SL lines are all kept at 0V and the BLR lines are also discharged to 0V. For the DRAM read operation, the corresponding SL line is pulled high and a voltage accumulation on the initially discharged line BLR is sensed to read the DRAM data. Note, all unselected SL lines are kept at 0V. The DRAM data can be read by using a large signal inverter based sensing as shown in FIG. 3. The compact inverter based sensing ensures minimal sensing circuit overhead. In summary, the transistors M3, M4 along with lines SL and BLR constitute an embedded DRAM cell within the 8T SRAM cell, such that it can store an independent data in a dynamic fashion, while simultaneously a static data is stored in the SRAM cell.

Interestingly, while transistors M3, M4 and node Vz store a DRAM-like data, the SRAM data is stored on nodes Vx and Vy which can be read and written by simultaneously activating worldines WL1 and WL2. The SRAM data can be read using a latch based differential current or voltage sense amplifier, as shown in FIG. 3. It is important to note that the DRAM data stored on node Vz will be destroyed during the read or write operation of the SRAM data since the DRAM node Vz is in the SRAM read/write path. However, this issue can be circumvented by relying on the data access pattern for specific end applications. For example, in a deep learning network nodes Vx and Vy can store weights while the corresponding node Vz streams input activations. In other words, by ensuring a first-in last-out (FILO) scheme for the combined SRAM-like and DRAM-like bit we can store two bits simultaneously in the 8T bit-cell without inadvertently destroying the DRAM data. Given the regular memory access pattern for data intensive applications like artificial intelligence and machine learning, it is easy to enforce such a FILO scheme.

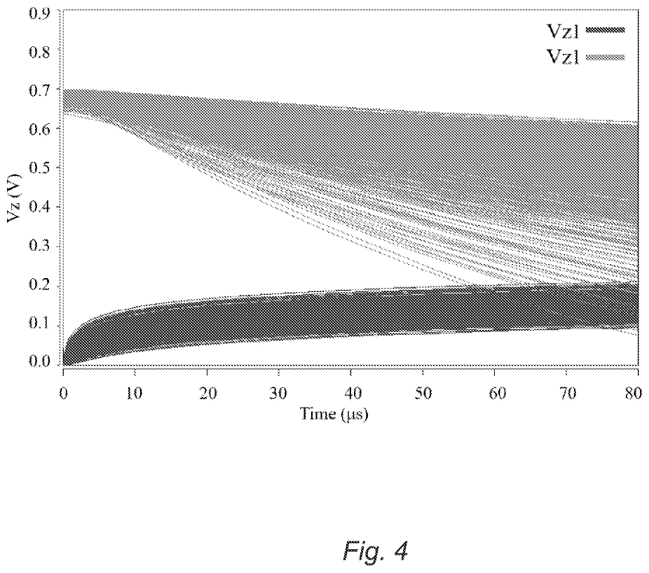

Thanks to the excellent leakage control of technologies like FD-SOI we have achieved 25 ms retention time at 85 C with a small (−100 mV negative voltage) on wordlines WL2 during hold mode of the memory array. Timing waveforms with Monte-Carlo simulations are shown in FIG. 4, exhibiting the retention waveform at a temperature of 85 degrees Celsius. The retention time is defined here as the time until the peripheral circuit can reliably sense the data stored on the dynamic node Vz.

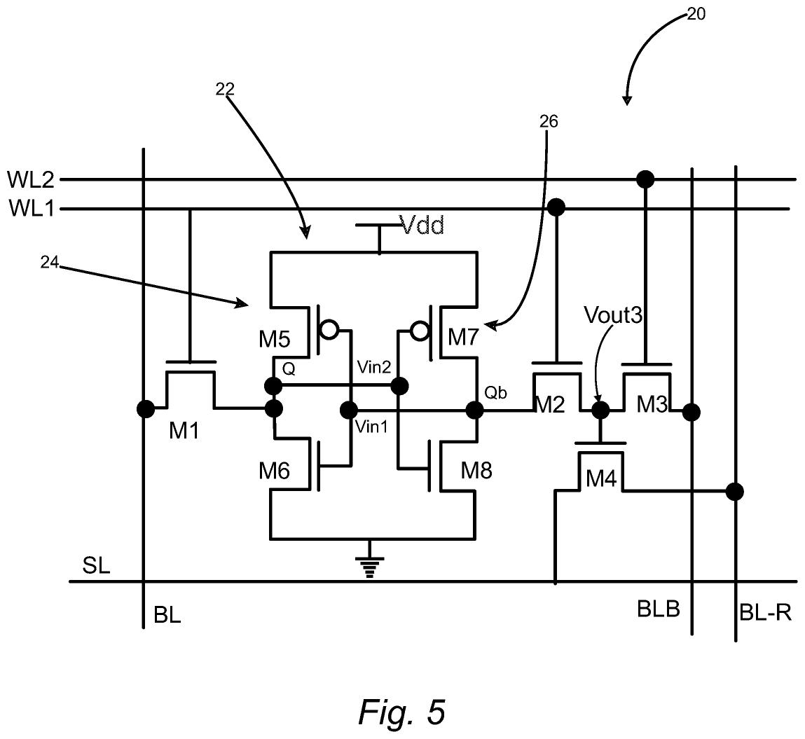

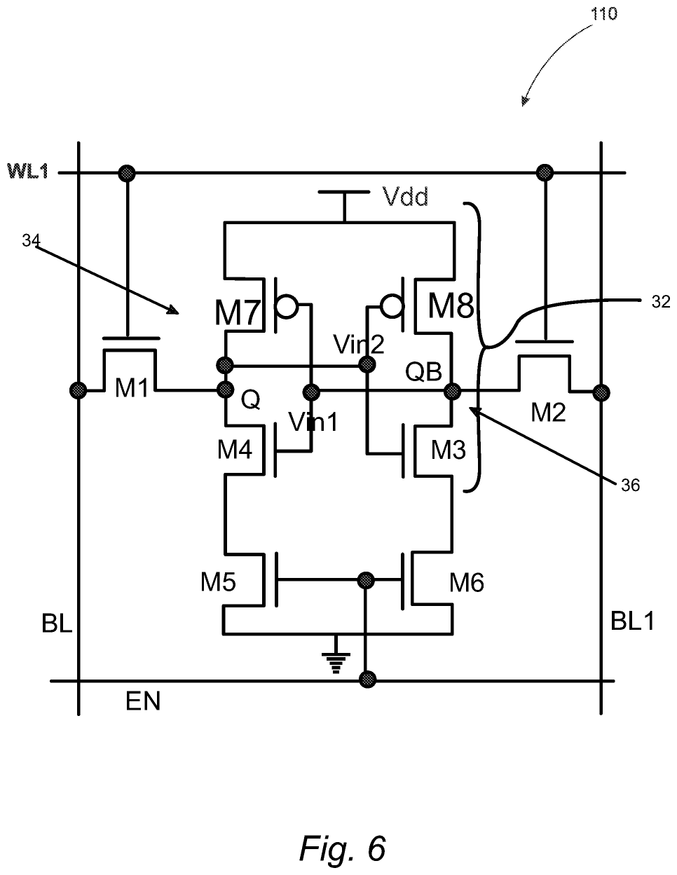

Referring to FIGS. 5 and 6, schematics of an SRAM-bit cell are provided. Each of the SRAM-bit cell includes two extra transistors as compared to the conventional 6T SRAM cell. The present invention provides a novel memory-centric approach called “Augmented Memory Computing” i.e. augmenting or increasing the memory storage capacity such that individual SRAM bit-cells can be dynamically reconfigured to store two bits of data instead of one. This augmented capacity comes at the cost of slightly degraded bit-cell robustness and read/write speed. Despite the degraded bit-cell robustness, the error-resilience of AI workloads can be leveraged to accelerate AI applications with no or minimal degradation to the end classification accuracy. Advantageously, the proposed augmented memory bit-cells (FIG. 5) can be combined with existing in-memory compute approaches well-known in the literature. Advantageously, augmented memory computing introduces a new memory-centric approach for efficient AI computations, which can also be used in conjunction with existing in-memory compute approaches for added benefit.

The transistors depicted in the electronic devices of FIGS. 5 and 6 are generally described as having a gate and two terminals (e.g., source and drain). In a refinement, each of the transistor in the figures are CMOS transistors. Each component described as a line is an electrical line. The SRAM-bit cell of FIGS. 5 and 6 each include a first transistor M1, a second transistor M2, a third transistor M3, a fourth transistor M4, a fifth transistor M5, a sixth transistor M6, a seventh transistor M7, and an eighth transistor M8:

Referring to FIG. 5, SRAM-bit cell 20 includes a four transistor SDRAM component 22 (e.g., a cross-coupled inverter) having a first transistor inverter 24 and a second transistor inverter 26. First transistor inverter 24 includes transistors M5 and M6 while second transistor inverter 26 includes transistors M7 and M8. In a refinement, the first transistor inverter 24 and a second transistor inverter 26 are CMOS inverters. Characteristically, the output (potential) Q of first transistor inverter 24 is provided as input Vin2 to the second transistor inverter 26, and the output (potential) QB of second transistor inverter 16 is provided as input Vin1 to the first transistor inverter 24. SRAM-bit cell 20 also includes access transistors M1 in electrical communication with the output of first transistor inverter 24 and first bit line BL (e.g., an inverse bit line). SRAM-bit cell 10 also includes access transistors M3 in electrical communication with the output of second transistor inverter 16 and second bit line BLB.

Still referring to FIG. 5, SRAM bit-cell 20 includes two additional transistors M2 and M4 (as compared to the conventional 6T SRAM cell). Transistor M2 is interposed between the output QB of the second transistor inverter 26 and a terminal of transistor M3. Additional transistor M4 is in electrical communication with the output Vout3 of the combination of transistors M2 and M3. In particular, output Vout3 is connected to the gate of additional transistor M4. Additional transistor M4 has a first terminal connected to line BL-R and a second terminal connected to line SL.

Characteristically, the wordline connected to M1-M2 is separate than the wordline driving M3.) When M1, M2, M3 are all ON, the cell functions similar to 6T SRAM bit-cell 2) When M1, M2 is ON and M3 is OFF the cell functions similar to conventional two port 8T SRAM bit-cell with a de-coupled read port, data being read by pulling SL high and sensing the voltage change on BL-R. 3) When M1, M2 is OFF and M3 is ON; M3 and M4 form the well-known two transistor gain cell DRAM. Note, in this configuration, the cross-coupled inverters can store one bit of data while another bit can be stored in the DRAM cell consisting of transistors M3 and M4. In this configuration, the presented 8T bit-cell can store one SRAM-like and one DRAM-like data, simultaneously; thereby dynamically increasing the memory storage capacity. It is to be noted that the DRAM-like bit would be destroyed while reading the SRAM-like bit, as such the DRAM data has to read first before the SRAM data. This, serial read of DRAM-like and SRAM-like data should not be of major concern for AI applications, since the SRAM-like data can store activations while the neural networks weights to be convolved with a given activation can stream through the DRAM-like storage. Additionally, given the low data reuse for AI applications no or minimal refresh would be required for the DRAM-like bit depending on the overall architecture.

Referring to FIG. 6, SRAM-bit cell 30 includes a four transistor SDRAM component 32 (e.g., a cross-coupled inverter) having a first transistor inverter 34, which and a second transistor inverter 36. The first transistor inverter 34 includes transistors M7 T1 and M7, while the second transistor inverter 36 includes transistors M8 T3 and M3. In a refinement, first transistor inverter 34 and a second transistor inverter 36 are CMOS inverters. Characteristically, the output (potential) Q of first transistor inverter 34 is provided as input Vin2 to the second transistor inverter 16, and the output (potential) QB of second CMOS inverter 36 is provided as input Vin1 to the first transistor inverter 34. Two additional transistors M5 and M6 are added with an additional line called EN. In a refinement, the gates of transistors M5 and M6 are connected to each other and to line EN. Terminals of transistor M5 are in series with the terminals of transistor M4 while terminals of transistor M6 are in series with the terminals of transistor M3. SRAM-bit cell 30 operates as follows:
1) When EN is ON, the bit-cell functions like 6T SRAM bit-cell
2) When EN is OFF, the bit-cell can store data in a dynamic format wherein (Q, QB), could either be (1,0), (0,1) or (1,1).

Note, in this configuration, the bit-cell can function like a dynamic ternary memory cell useful for the on-demand acceleration of ternary neural networks. Also depicted in FIG. 6, SRAM-bit cell 30 includes first access transistor M1 with a terminal connected to the output Q of first transistor inverter 34 and a terminal connected to line BL. SRAM-bit cell 30 also includes a second access transistor M2 with a terminal connected to the output QB of first transistor inverter 36 and a terminal connected to line BL1.

A key benefit of augmented memory computing with respect to in-memory computing is the fact that augmented memory computing does not require heavily modified ISA (instruction set architecture), which makes it easier to incorporate it in large-scale processors and cache without concern for backward compatibility of the ISA. Nevertheless, if desired, augmented memory computing can be combined with in-memory computing techniques.

In another embodiment, a 7T augmented SRAM cells are provided. It is well-known that a 6 transistor SRAM cell can store one digital bit in a static format. SRAM being a differential memory, both the bit and the complement of the bit are stored in the same cell. The 7T augmented SRAM cells provided herein can either be configured to store one static SRAM bit (Two Levels: Normal mode of operation) or one dynamic ternary bit (Three Levels: Augmented mode of operation). Note, ternary bits have three levels usually represented as (−1, 0, +1).

Ternary memory storage is becoming increasingly popular due to the recent algorithmic advances in Ternary Neural Networks (TNNs). TNNs are being extensively explored [15], [16], since they provide both lower memory requirement as well as improved accuracy for deep learning networks. Traditionally, since 6T SRAM cell can only store a binary data, two 6T cells are required to store one ternary data [17]. As such, our proposed 7T Ternary augmented cell can be configured to increase the on-chip SRAM storage density for ternary weights for TNN accelerators. Note, the proposed 7T Ternary augmented cell stores ternary data in a dynamic format as opposed to the conventional 6T SRAM, which stores static binary data.

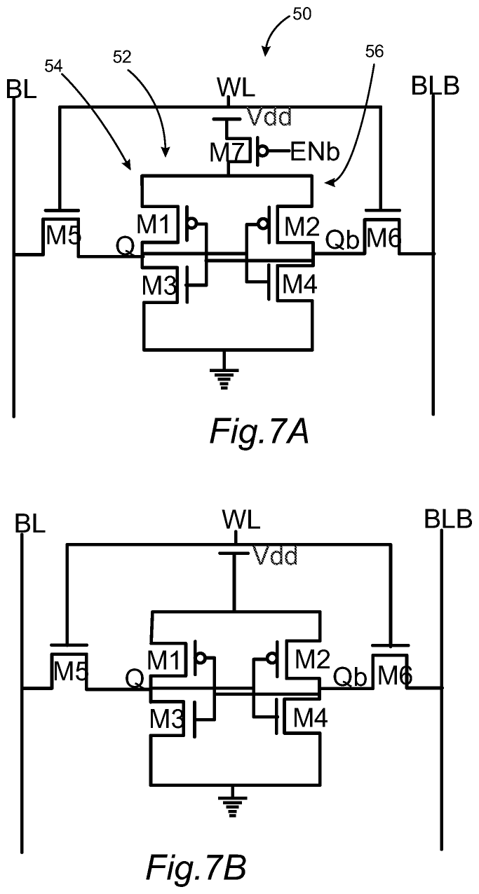

With reference to FIGS. 7A and 7B, a schematic of a 7T Ternary augmented cell is shown. A 7T Ternary augmented cell 50 includes a first transistor M1, a second transistor M2, a third transistor M3, a fourth transistor M4, a fifth transistor M5, a sixth transistor M6, and a seventh transistor M7. The 7T Ternary augmented cell 50 includes a four transistor SDRAM component 52 (e.g., a cross-coupled inverter) having a first transistor inverter 54 and a second transistor inverter 56. First transistor inverter 54 includes transistors M1 and M3 while second transistor inverter 56 includes transistors M2 and M4. In a refinement, the first transistor inverter 14 and the second transistor inverter 16 are CMOS inverters. In other words, 7T Ternary augmented cell 50 includes a 6T SRAM cell with one additional PMOS transistor per bit-cell connecting the cross-coupled inverters to VDD. For the Normal mode of operation, the PMOS M7 is kept ON, and the augmented cell functions similar to a normal SRAM cell. It is worth mentioning, that similar 7T cells with a header PMOS have been used in previous literature to enable fine-grained power gating [18]. In the traditional use-case, when the PMOS transistor M7 is switched OFF, the cross-coupled inverters are disconnected from the power supply and the SRAM cell enters power-gated mode, thereby drastically reducing the cell leakage. In summary, the normal mode of operation of the 7T augmented cell is similar to a gated VDD SRAM cell [18]. When PMOS M7 is ON, the cell stores one static data, when PMOS M7 is OFF, the cell is disconnected from VDD and is in power gated mode.

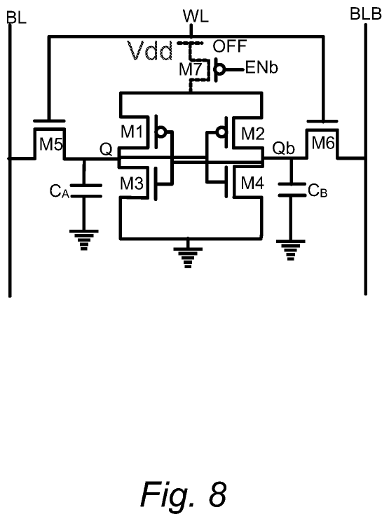

Referring to FIG. 8, during the Augmented mode, transistor M7 is switched OFF. As seen in FIG. 8, the cross-coupled inverters are disconnected from VDD, and the SRAM can no longer store data and its complement in static format. With PMOS M7 OFF, since the cross-coupled inverters are no longer connected to VDD, the positive feedback behavior of the cross-coupled inverters are weakened. We exploit this weakened feedback between the nodes Q and QB to store three different data patterns on nodes (Q,QB) in a dynamic fashion. Specifically, with the PMOS M7 OFF, (Q,QB) can dynamically store one among three different data patterns—(1,0), (0,1) and (0,0). This three level storage allows us to store a ternary bit in the 7T SRAM cell, wherein (1,0), (0,1) and (0,0) can be conceptually mapped to ternary levels of (−1,+1, 0), respectively.

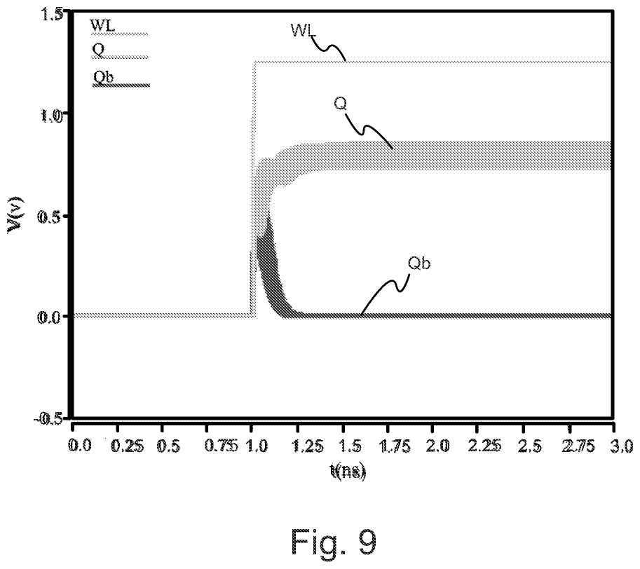

The storage of different voltage levels on nodes Q and QB can be understood as follows. Let us consider the case of storing the data (0,1) in the SRAM cell during the Augmented mode (i.e. when PMOS M7 is OFF). Keeping PMOS M7 OFF, the WL is activated, BL and BLB are pulled high or low based on the data to be stored in the SRAM cell. Note, since the SRAM cell is not connected to VDD, the cross-coupled inverter does not have a positive feedback mechanism to write a robust ‘1’ into the cell. This is because the access transistors consisting of NMOS devices suffer a threshold voltage (VT) drop when passing a high value. Consequently, we use voltage boosting, wherein the WL is pulled to 1.25V to ensure a strong ‘1’ is written into the SRAM cell. The write waveforms for storing data (0,1) is shown in FIG. 9. Note, with PMOS M7 OFF, when Q and QB stores (0,1), the DRAM-like capacitors CA and CB (formed due to parasitic gate and diffusion capacitances) are charged and discharged, respectively (see FIG. 8). As a result, transistors M2 and M3 are ON and M1 and M4 are OFF. By symmetry, the waveforms of FIG. 9 also represent write operation for data (1,0) with appropriate voltages being applied on BL and BLB.

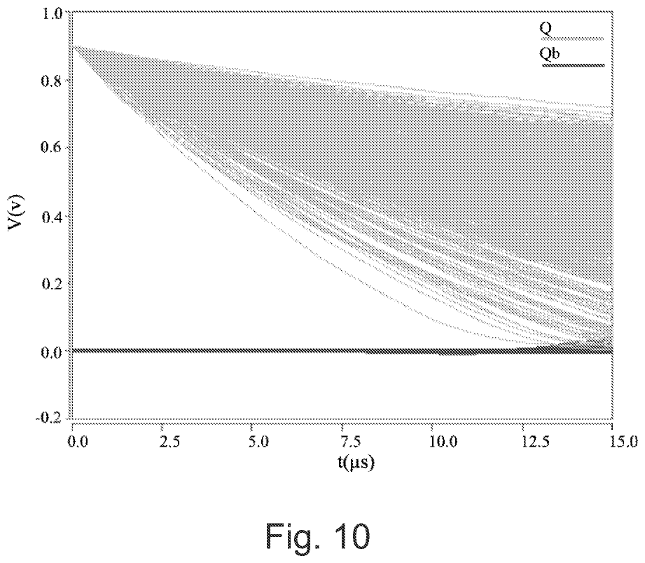

As expected, due to absence of a VDD connection, over a certain duration of time, the dynamic nodes Q and QB leak, destroying the data stored in the augmented cell. Thereby, with respect to (0,1) data, the retention time can be defined as the time up to which the data Q and QB can be robustly sensed by the peripheral sensing circuit. A similar argument for retention time can also be made for data (1,0). Figure showing the leakage of voltages on nodes Q and QB that dictates the retention time for data (0,1)/(1,0) is depicted in FIG. 10.

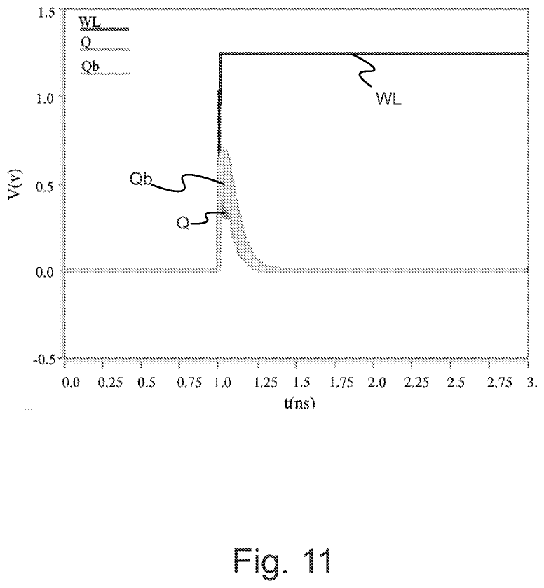

Now let us consider storing data (0,0) in the augmented 7T cell. For writing the data (0,0), both Q and QB are discharged by activating the WL and pulling BL and BLB to 0V. This in turn switches OFF NMOS transistors M3 and M4. Although the PMOSes M1 and M2 are ON, nodes Q and QB are disconnected from VDD due to the OFF transistor M7. As a result, nodes Q and QB are not connected to VDD. The capacitors CA and CB act as dynamic floating nodes that are neither connected to GND nor to VDD. Thus, the dynamic nodes Q and QB store the data (0,0) when BL and BLB are pulled low and WL is high. The write waveforms for data (0,0) is shown in FIG. 11. Note, in a conventional 6T SRAM cell, storage of (0,0) is not possible due to the existence of strong positive feedback between the two cross-coupled inverters. The strong positive feedback forces Q and QB to always be the complement of each other. By disconnecting the VDD using PMOS M7, we significantly weaken the feedback connection and store (0,0) on nodes (Q,QB) on the dynamic capacitors CA and CB. In summary, when PMOS M7 is switched OFF, the 7T cell can either store (1,0), (0,1), or (0,0) in a dynamic manner. Note, as expected the data (0,0) stored on dynamic nodes Q and QB leak with time. However, the resulting retention time is higher than the case of (0,1) and (1,0). Consequently, the (0,0) data storage does not decide the overall retention of the 7T augmented cell, it is rather limited by the retention time of data (0,1)/(1,0) as shown in FIG. 10.

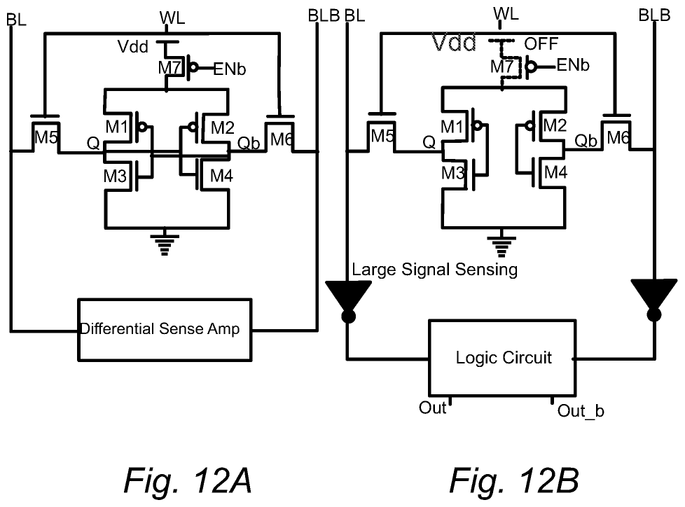

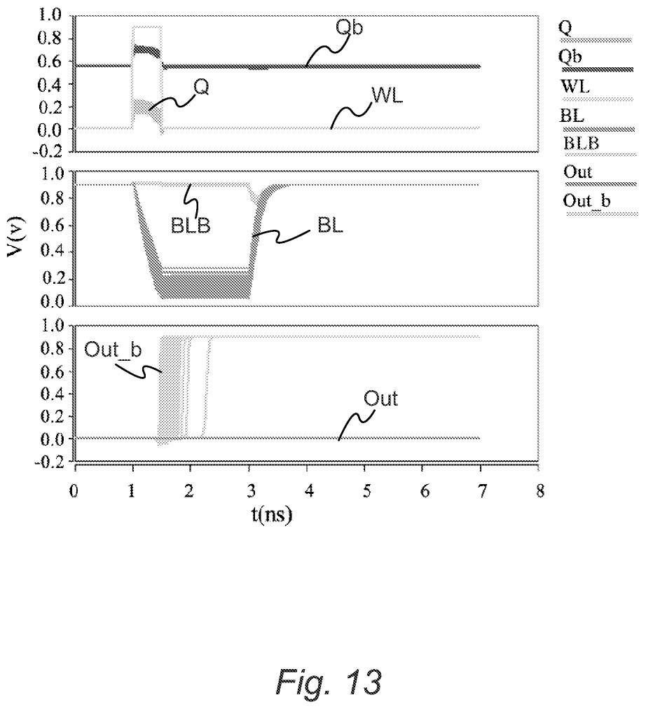

Let us now consider the readout of data (0,1), (1,0) and (0,0). For a (0,1) or (1,0) readout, one of the NMOS transistors M3 or M4 is ON depending on the data stored in the bitcell. When WL is made ON by pulling it to VDD, the precharged BL or BLB discharges depending on which among NMOS transistors M3 or M4 is ON. Thus, by sensing the discharge on BL and BLB, the peripheral circuit can conclude if the data stored in the augmented 7T cell is (0,1) and (1,0), respectively. In its simplest form, the readout circuit consists of large-signal inverter-based sensing, as shown in FIG. 12 (B). On the other hand, for the data (0,0), both the NMOS transistors are OFF and both BL and BLB do not see a significant discharge except for leakage currents. As such, no significant voltage discharge either on BL or BLB indicates storage of data (0,0). In summary, a discharging BL indicates data (0,1), a discharging BLB indicates storage of data (1,0), and no significant discharge either on BL or BLB indicates data (0,0). The logic circuit shown in FIG. 12(B) takes the voltage output from the sensing inverters as input digital signal and converts it into (0,1), (1,0), or (0,0) representing the data stored in the 7T SRAM cell. Read waveforms for reading the data (0,1) is shown in FIG. 13. By symmetry, the waveforms also represent the readout of data (1,0). Note, in the case of (0, 0), both BL and BLB would not show any significant discharge during the read operation, as such, the waveforms for (0, 0) read are not shown explicitly in the figure. It is worth mentioning, during Normal SRAM operation i.e. when PMOS transistor M7 is ON the 7T SRAM cell functions like a standard 6T cell that can be sensed using a standard differential sensing amplifier. In addition, one could also use two differential sense amplifiers, one on each BL and BLB for small signal single ended sensing instead of large signal-sensing that uses inverters. Although such differential sensing during augmented mode has speed benefits, it suffers from area overhead drawback.

Additional details of the present invention are set forth in arXiv:2109.03022v1 [cs.AR](doi.org/10.48550/arXiv.2109.03022); the entire disclosure of which is hereby incorporated by reference.

The following examples illustrate the various embodiments of the present invention. Those skilled in the art will recognize many variations that are within the spirit of the present invention and scope of the claims.

### Results And Discussions

As discussed earlier, the proposed augmented bit-cells can be operated in two modes—the Normal mode and the Augmented mode. In essence, augmented cells rely on dynamic storage within the SRAM cells to increase the memory storage capacity. Due to such dynamic nature of storage, retention time is the key metric for augmented bit-cells. Furthermore, the retention time shows a strong dependence on temperature and makes our proposed cells interesting for cryo-computing applications [19]. Table I-II mentions the retention time for various temperatures. The retention time is a strong function of temperature and are in similar range as reported in previous works on embedded-DRAM cells [20]. The retention time can be improved using circuit based design knobs like body biasing [21] etc. In addition, based on the end application requirement, a hardware-algorithm co-design approach can be used to allow relaxed retention times by leveraging the resiliency of the end application, for example, the resilient nature of a deep learning network can be used to extend the retention time of the augmented bit-cells using error-aware training of the neural network.

TABLE I
SUMMARY OF RETENTION TIME FOR
8T SRAM AUGMENTED BIT-CELL

| Temperature | VWL1 | VWL2 | Retention time |
|---|---|---|---|
| 85° C. | −0.1 V | 0 V | 25 μs |
| 25° C. | 0 V | 0 V | 250 μs |
| 25° C. | −0.1 V | 0 V | milli-sec |

TABLE II
SUMMARY OF RETENTION TIME FOR
7T SRAM AUGMENTED BIT-CELL

| Temperature | VWL | Retention time |
|---|---|---|
| 85° C. | 0 V | 4 μs |
| 25° C. | 0 V | >50 μs |

In Table III-IV we have enumerated read, write energy associated with the augmented cells in Normal and Augmented modes along with leakage power consumption. For the sake of comparison, we have also mentioned the energy and delay numbers for conventional 6T SRAM cell at 22 nm Globalfoundries FDX technology. All the energy and power numbers are reported for operation at a temperature of 85 C. For the 8T augmented cell, the read, write energy and leakage power increases as compared to a 6T cell. This increase can be attributed to a greater number of transistors in the augmented cell, that add both parasitic capacitance and leakage energy consumption. Also, it was observed due to the use of single ended sensing for the DRAM part of the 8T augmented cell the read energy increases by 2.7× compared to the 6T cell. For the 7T augmented cell, the energy metrics are comparable to the 6T SRAM cell for Normal mode of operation. The reduced write energy can be attributed to the OFF PMOS header transistor in the augmented mode making write operation easier and reducing cell leakage for unselected rows. Table V-VI report the read and write time for the augmented mode operation. Note, due to the presence of BL and BLB the read delay for 7T bit-cell is lesser as compared to the 8T bit-cell. The delay number for 8T bit-cell is for the DRAM-like bit, the SRAM-like bit storage has similar read, write delay as a normal 6T SRAM cell.

TABLE III
POWER/ENERGY CONSUMPTION
OF 8T SRAM AUGMENTED CELL

| Temperature | Region | 6T SRAM | | 8T SRAM | |
|---|---|---|---|---|---|
| 85° C. | Hold | 0.448 | uW | 0.603 | uW |
| 85° C. | Read | 1.83 | fJ | 3.37 | fJ |
| 85° C. | Write | 2.07 | fJ | 8.32 | fJ |

TABLE IV
POWER/ENERGY CONSUMPTION
OF 7T SRAM AUGMENTED CELL

| Temperature | Operation | 6T SRAM | | 7T-Normal | | 7T-AMC | |
|---|---|---|---|---|---|---|---|
| 85° C. | Hold | 0.448 | uW | 0.430 | uW | 0.59 | uW |
| 85° C. | Read | 1.83 | fJ | 3.53 | fJ | 3.12 | fJ |
| 85° C. | Write | 2.07 | fJ | 2.02 | fJ | 0.99 | fJ |

TABLE V
SUMMARY OF READ AND WRITE DELAY
FOR 8T SRAM AUGMENTED CELL

| Write Delay | Read Delay |
|---|---|
| 1 ns | 15 ns |

TABLE VI
SUMMARY OF READ AND WRITE DELAY
FOR 7T SRAM AUGMENTED CELL

| | Write Delay | Read Delay |
|---|---|---|
| Data (0, 0) | 0.4 ns | 0.4 ns |
| Data (0, 1)/(1, 0) | 0.5 ns | 1.5 ns |

Let us now highlight some key discussions with respect to the augmented memory bit-cells. As detailed in the manuscript, augmented memory bit-cells bring in a novel approach to dynamically increase the memory storage capacity. As such, the augmented bit-cells help to alleviate the issues associated with limited on-chip storage. On the other hand, in-memory computing is another well-known approach being extensively investigated by the research community [7], [11], [22]. Below are the key points we would like to highlight about augmented memory with respect to in-memory computing.

AMC aims at dynamically increasing on-chip storage capacity through modified SRAM bit-cells. It is important to note that, use of augmented mode does not incur any approximation in data storage or computed data. The sole difference between normal SRAM and augmented storage is the dynamic nature of data and does not affect the accuracy of computations. This is in contrast to in-memory computing paradigms, wherein multiple rows are activated and computations are achieved through approximation of the accumulated signal on the bit-lines. Thus, AMC paradigm is more amenable to traditional memory verification and design flow than in-memory paradigms.

Interestingly, augmented memory computing can be combined with in-memory computing techniques for additional benefits. Both analog and digital in-memory computing techniques have been presented in various previous works for static (SRAM) [22] and dynamic (DRAM) bit-cells [23]. These in memory techniques can be easily applied to the AMC bitcells (specifically the 8T dual bit AMC cell) while operating in augmented computing mode. For example, the 8T dual bit-cell can be configured to store one SRAM-like and one DRAM-like data. During read operation multiple wordlines can be activated and digital or analog in-memory computing can be achieved while the 8T cell is operating in augmented memory mode. The FILO readout for 8T augmented bit-cell could still be enforced while performing in-memory computing operations to ensure the DRAM data is not inadvertently destroyed while accessing the SRAM data. Further, algorithm hardware co-design can be invoked to leverage trade-off between retention time, power consumption and end application accuracy [24], [25]. Augmented bit-cells thus provide multiple operational mode—1) the Normal mode, 2) only Augmented computing mode, 3) only in-memory computing mode, and 4) Augmented+in-memory/near-memory computing mode.

### CONCLUSION

On-chip memory capacity is a key factor for many data intensive applications. In this paper, for the first time, we propose novel augmented memory bit-cells that can operate like conventional SRAM cells during normal mode of operation and can dynamically increase their storage capacity in the augmented mode of operations. We specifically present an 8 transistor SRAM cell that can store one SRAM-like and one DRAM-like bit, simultaneously, within the memory bit-cell. Similarly, our proposed 7 transistor SRAM bit-cell can store a ternary bit (three levels) in a dynamic fashion during the augmented mode of operation. Advantageously, the presented augmented bit-cells are amenable to in-memory compute paradigm that can provide added energy and throughput benefits. The functionality of the presented bit-cells has been confirmed by extensive simulations at Globalfoundries 22 nm FD-SOI technology node. In summary, the concept of augmented memory bit-cells brings in a new dimension to accelerate data intensive application by dynamically augmenting the on-chip memory storage capacity.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

### REFERENCES

[1] J. Shalf, “The future of computing beyond moore's law,” Philosophical Transactions of the Royal Society A, vol. 378, no. 2166, p. 20190061, 2020.
[2] D. Gil and W. M. Green, “1.4 the future of computing: Bits+ neurons+ qubits,” in 2020 IEEE International Solid-State Circuits Conference—(ISSCC). IEEE, 2020, pp. 30-39.
[3] N. R. Mahapatra and B. Venkatrao, “The processor-memory bottleneck: problems and solutions,” Crossroads, vol. 5, no. 3es, p. 2, 1999.
[4] Y.-D. Chih, Y.-C. Shih, C.-F. Lee, Y.-A. Chang, P.-H. Lee, H.-J. Lin, Y.-L. Chen, C.-P. Lo, M.-C. Shih, K.-H. Shen et al., “13.3 a 22 nm 32mb embedded stt-mram with 10 ns read speed, 1 m cycle write endurance, 10 years retention at 150° C. and high immunity to magnetic field interference,” in 2020 IEEE International Solid-State Circuits Conference—(ISSCC). IEEE, 2020, pp. 222-224.
[5] H.-S. P. Wong, S. Raoux, S. Kim, J. Liang, J. P. Reifenberg, B. Rajendran, M. Asheghi, and K. E. Goodson, “Phase change memory,” Proceedings of the IEEE, vol. 98, no. 12, pp. 2201-2227, 2010.
[6] A. Agrawal, A. Jaiswal, C. Lee, and K. Roy, “X-sram: Enabling inmemory boolean computations in cmos static random access memories,” IEEE Transactions on Circuits and Systems I: Regular Papers, vol. 65, no. 12, pp. 4219-4232, 2018.
[7] A. Sebastian, M. Le Gallo, R. Khaddam-Aljameh, and E. Eleftheriou, “Memory devices and applications for in-memory computing,” Nature nanotechnology, vol. 15, no. 7, pp. 529-544, 2020.
[8] J. P. Kulkarni, A. Malavasi, C. Augustine, C. Tokunaga, J. Tschanz, M. Khellah, and V. De, “Low swing and column multiplexed bitline techniques for low-vmin, noise-tolerant, high-density, 1r1w 8t-bitcell sram in 10 nm finfet cmos,” in 2020 IEEE Symposium on VLSI Circuits. IEEE, 2020, pp. 1-2.
[9] T. Song, J. Jung, W. Rim, H. Kim, Y. Kim, C. Park, J. Do, S. Park, S. Cho, H. Jung et al., “A 7 nm finfet sram using euv lithography with dual write-driver-assist circuitry for low-voltage applications,” in 2018 IEEE International Solid-State Circuits Conference-(ISSCC). IEEE, 2018, pp. 198-200.
[10] H. Ahmad, T. Arif, M. A. Hanif, R. Hafiz, and M. Shafique, “Superslash: A unified design space exploration and model compression methodology for design of deep learning accelerators with reduced off-chip memory access volume,” IEEE Transactions on Computer-Aided Design of Integrated Circuits and Systems, vol. 39, no. 11, pp. 4191-4204, 2020.
[11] A. Jaiswal, I. Chakraborty, A. Agrawal, and K. Roy, “8t SRAM cell as a multi-bit dot product engine for beyond von-neumann computing,” arXiv preprint arXiv:1802.08601, 2018.
[12] X. Si, W.-S. Khwa, J.-J. Chen, J.-F. Li, X. Sun, R. Liu, S. Yu, H. Yamauchi, Q. Li, and M.-F. Chang, “A dual-split 6t sram-based computing in-memory unit-macro with fully parallel product-sum operation for binarized dnn edge processors,” IEEE Transactions on Circuits and Systems I: Regular Papers, vol. 66, no. 11, pp. 4172-4185, 2019.
[13] “Globalfoundries 22fdx: 22 nm fd-soi technology,” [Online] http://www.hpl.hp.com/research/cacti/.
[14] M. Khellah, Y. Ye, N. Kim, D. Somasekhar, G. Pandya, A. Farhang, K. Zhang, C. Webb, and V. De, “Wordline & bitline pulsing schemes for improving sram cell stability in low-vcc 65 nm cmos designs,” in 2006 Symposium on VLSI Circuits, 2006. Digest of Technical Papers. IEEE, 2006, pp. 9-10.
[15] H. Alemdar, V. Leroy, A. Prost-Boucle, and F. P'etrot, “Ternary neural networks for resource-efficient ai applications,” in 2017 international joint conference on neural networks (IJCNN). IEEE, 2017, pp. 2547-2554.
[16] N. Mellempudi, A. Kundu, D. Mudigere, D. Das, B. Kaul, and P. Dubey, “Ternary neural networks with fine-grained quantization,” arXiv preprint arXiv:1705.01462, 2017.
[17] S. Jain, S. K. Gupta, and A. Raghunathan, “Tim-dnn: Ternary in-memory accelerator for deep neural networks,” IEEE Transactions on Very Large Scale Integration (VLSI) Systems, vol. 28, no. 7, pp. 1567-1577, 2020.
[18] M. Powell, S.-H. Yang, B. Falsafi, K. Roy, and T. Vijaykumar, “Gatedvdd: A circuit technique to reduce leakage in deep-submicron cache memories,” in Proceedings of the 2000 international symposium on Low power electronics and design, 2000, pp. 90-95.
[19] H. Chiang, T. Chen, J. Wang, S. Mukhopadhyay, W. Lee, C. Chen, W. Khwa, B. Pulicherla, P. Liao, K. Su et al., “Cold cmos as a powerperformance—reliability booster for advanced finfets,” in 2020 IEEE Symposium on VLSI Technology. IEEE, 2020, pp. 1-2.
[20] R. Giterman, A. Fish, A. Burg, and A. Teman, “A 4-transistor nmos-only logic-compatible gain-cell embedded dram with over 1.6-ms retention time at 700 my in 28-nm fd-soi,” IEEE Transactions on Circuits and Systems I: Regular Papers, vol. 65, no. 4, pp. 1245-1256, 2017.
[21] J. Narinx, R. Giterman, A. Bonetti, N. Frigerio, C. Aprile, A. Burg, and Y. Leblebici, “A 24 kb single-well mixed 3t gain-cell edram with body-bias in 28 nm fd-soi for refresh-free dsp applications,” in 2019 IEEE Asian Solid-State Circuits Conference (A-SSCC). IEEE, 2019, pp. 219-222.
[22] A. Agrawal, A. Jaiswal, C. Lee, and K. Roy, “X-SRAM: Enabling inmemory boolean computations in CMOS static random access memories,” IEEE Transactions on Circuits and Systems I: Regular Papers, pp. 1-14, 2018.
[23] M. F. Ali, A. Jaiswal, and K. Roy, “In-memory low-cost bit-serial addition using commodity dram technology,” IEEE Transactions on Circuits and Systems I: Regular Papers, vol. 67, no. 1, pp. 155-165, 2019.
[24] J. Liu, B. Jaiyen, R. Veras, and O. Mutlu, “Raidr: Retention-aware intelligent dram refresh,” ACM SIGARCH Computer Architecture News, vol. 40, no. 3, pp. 1-12, 2012.
[25] R. Giterman, A. Bonetti, A. Burg, and A. Teman, “Gc-edram with bodybias compensated readout and error detection in 28-nm fd-soi,” IEEE Transactions on Circuits and Systems II: Express Briefs, vol. 66, no. 12, pp. 2042-2046, 2019.

What is claimed is:

1. A SRAM-bit cell comprising a first transistor M1, a second transistor M2, a third transistor M3, a fourth transistor M4, a fifth transistor M5, a sixth transistor M6, a seventh transistor M7, and an eighth transistor M8,
wherein a four transistor SDRAM component includes a first transistor inverter and a second transistor inverter, the first transistor inverter including the fifth transistor M5 and the sixth transistor M6 and the second transistor inverter including the seventh transistor M7 and the eighth transistor M8;
wherein an output Q of the first transistor inverter is provided as input Vin2 to the second transistor inverter and an output QB of the second transistor inverter is provided as an input Vin1 to the first transistor inverter;
wherein the first transistor M1 is a first access transistor in electrical communication with the output Q of the first transistor inverter and first bit line BL;
wherein the third transistor M3 is a second access transistor is in electrical communication with the output QB of second transistor inverter and a second bit line BLB;
wherein the second transistor M2 is a first additional transistor;
wherein the fourth transistor M4 is a second additional transistor;
wherein the second transistor M2 is interposed between the output QB of second transistor inverter and a terminal of the third transistor M3 with terminals of the second transistor M2 and the third transistor M3 connected in series;
wherein an output Vout3 of a combination of the second transistor M2 and the third transistor M3 is in electrical communication with a gate of the fourth transistor M4, the fourth transistor M4 having a first terminal connected to line BL-R and a second terminal connected to line SL; and
wherein the first transistor M1 and the second transistor M2 are connected to a first wordline and the third transistor M3 is connected to a second wordline.

2. The SRAM-bit cell of claim 1 wherein the first transistor inverter and the second transistor inverter are CMOS inverters.

3. The SRAM-bit cell of claim 1 configured such that when the first transistor M1, the second transistor M2, and the third transistor M3 are all ON, the SRAM-bit cell functioning as a 6T SRAM bit-cell 2.

4. The SRAM-bit cell of claim 3 configured such that when the first transistor M1, the second transistor M2 is ON and the third transistor M3 is OFF with the SRAM-bit cell functioning similar to conventional two port 8T SRAM bit-cell with a de-coupled read port, data being read by pulling SL high and sensing a voltage change on BL-R.

5. The SRAM-bit cell of claim 4 configured such that when the first transistor M1, the second transistor M2 is OFF and the third transistor M3 is ON.

6. A SRAM-bit cell comprising a first transistor M1, a second transistor M2, a third transistor M3, a fourth transistor M4, a fifth transistor M5, a sixth transistor M6, a seventh transistor M7, and an eighth transistor M8,
wherein a four transistor SDRAM component includes a first transistor inverter and a second transistor inverter, the first transistor inverter includes the seventh transistor M7 and the fourth transistor M4 and the second transistor inverter includes the eighth transistor M8 and the third transistor M3 wherein an output Q of first transistor inverter is provided as input Vin2 to the second transistor inverter and an output QB of second transistor inverter is provided as an input Vin1 to the first transistor inverter;
wherein the fifth transistor M5 is a first additional transistor and the sixth transistor is a second additional transistor;
wherein gates of the fifth transistor M5 and the sixth transistor M6 are connected to each other and to additional line EN and wherein terminals of the fifth transistor M5 are in series with terminals of the fourth transistor M4 while terminals of the sixth transistor M6 are in series with terminals of the third transistor M3;
wherein the first transistor M1 is a first access transistor having a terminal connected to output Q of the first transistor inverter and a terminal connected to line BL; and
wherein the second transistor M2 is a second access transistor having a terminal connected to output QB of the first transistor inverter and to line BL1.

7. The SRAM-bit cell of claim 6 configured such that when line EN is ON, the SRAM-bit cell functions like 6T SRAM bit-cell.

8. The SRAM-bit cell of claim 6 configured such when line EN is OFF, the SRAM-bit cell stores data in a dynamic format wherein (Q, QB), are (1,0) or (0,1) or (1,1).

9. The SRAM-bit cell of claim 6 wherein all transistors are CMOS transistors.

10. A SRAM-bit cell comprising a first transistor M1, a second transistor M2, a third transistor M3, a fourth transistor M4, a fifth transistor M5, a sixth transistor M6, a seventh transistor M7, and an eighth transistor M8,
wherein a four transistor cross-coupled inverter component includes a first transistor inverter and a second transistor inverter, the first transistor inverter including the fifth transistor M5 and the sixth transistor M6 connected at a first node Vx and the second transistor inverter including the seventh transistor M7 and the eighth transistor M8 connected at a second node Vy;
wherein the first transistor M1 is a first access transistor in electrical communication with the gates of the seventh transistor M7 and the eighth transistor M8 which are connected together, the first transistor M1 also being in electrical communication with a first bit line BL;
wherein the second transistor M2 is a first additional transistor in electrical communication with the gates of transistor the fifth transistor M5 and the sixth transistor M6 which are connected together, the gates of both the first transistor M1 and the second transistor M2 are in electrical communication with a wordline WL1; and
wherein the third transistor M3 is a second access transistor M3 in electrical communication with the second transistor M2 both of which are in electrical communication with the gate of the fourth transistor M4 at a dynamic node Vz, the fourth transistor M4 being in electrical communication with line SL and line BLR, the gate of the third transistor M3 is in electrical communication with wordline WL2, the third transistor M3 is also in electrical communication with second bit line BLB.

11. The SRAM-bit cell of claim 10, wherein for the Normal mode of operation, both the wordlines WL1 and WL2 are activated, simultaneously

12. The SRAM-bit cell of claim 10, wherein during Normal mode, the SL line and the BLR line are kept at about 0V to ensure no current flows through the fourth transistor M4, irrespective of a voltage at its gate.

13. The SRAM-bit cell of claim 10, wherein in augmented mode, two bits of data are simultaneously stored.

14. The SRAM-bit cell of claim 10, wherein SRAM-like static data is stored in the cross-coupled inverter as complementary voltages on nodes Vx and Vy, while the third transistor M3 and the fourth transistor M4 store a DRAM-like data on the dynamic node Vz.

15. The SRAM-bit cell of claim 10 further comprising a differential sense amplifier for SRAM in electrical communication with the first bit line BL and the second bit line BLB.

16. The SRAM-bit cell of claim 10 wherein all transistors are CMOS transistors.

17. A SRAM-bit cell comprising a first transistor M1, a second transistor M2, a third transistor M3, a fourth transistor M4, a fifth transistor M5, a sixth transistor M6, and a seventh transistor M7,
wherein a cross-coupled inverters component includes a first transistor inverter and a second transistor inverter, the first transistor inverter including the first transistor M1 and the third transistor M3 and the second transistor inverter including the second transistor M2 and the fourth transistor M4;
wherein the fifth transistor M5 is a first access transistor in electrical communication with an output Q of the first transistor inverter and the gates of the second transistor M1 and the fourth transistor M3 which are connected together, the fifth transistor M5 also being in electrical communication with a first bit line BL;
wherein the sixth transistor M6 is a second access transistor in electrical communication with an output Qb of the second transistor inverter and the gates of the first transistor M1 and the third transistor M3 which are connected together, the sixth transistor M6 also being in electrical communication with a second bit line BLB; and
wherein the seventh transistor M7 connects the cross-coupled inverter component to supply voltage VDD.

18. The SRAM-bit cell of claim 17, wherein during Normal mode of operation, the seventh transistor M7 is kept ON.

19. The cell of claim 17, wherein during Augmented mode, the seventh transistor M7 is switched OFF such that three different data patterns are stored on nodes (Q,QB) in a dynamic fashion.

20. The SRAM-bit cell of claim 10 wherein all transistors are CMOS transistors.
